(19) United States
(12) Patent Application Publication
(10) Pub. No.: US 2024/0014798 A1
(43) Pub. Date: Jan. 11, 2024

(54) RESONATOR DEVICE

(71) Applicant: SEIKO EPSON CORPORATION, Tokyo (JP)

(72) Inventors: Taichi Fujinami, Shiojiri-shi (JP); Ryuta Nishizawa, Nagano-shi (JP); Shinya Aoki, Minowa-machi (JP); Shoichiro Kasahara, Minowa-machi (JP)

(21) Appl. No.: 18/347,856

(22) Filed: Jul. 6, 2023

(30) Foreign Application Priority Data
Jul. 8, 2022 (JP) 2022-110253

(51) Int. Cl. H03H 9/05; H03H 9/10; H03H 9/19

(52) U.S. Cl. CPC H03H 9/0547; H03H 9/1021; H03H 9/19

(57) ABSTRACT

A resonator device includes: a resonator; an integrated circuit device configured to oscillate the resonator and to generate an oscillation signal; a container accommodating the resonator and the integrated circuit device; and a metal bump bonded to the integrated circuit device and electrically coupling the integrated circuit device and the container. The integrated circuit device includes a pad bonded to the metal bump, and a circuit disposed at a position overlapping the metal bump in a plan view of the pad, and W1/W2≥1.08, where W1 represents a width of the pad, and W2 represents a width of the metal bump.

The present application is based on, and claims priority from JP Application Serial Number 2022-110253, filed Jul. 8, 2022, the disclosure of which is hereby incorporated by reference herein in its entirety.

### BACKGROUND

### 1. Technical Field

The present disclosure relates to a resonator device.

### 2. Related Art

In a semiconductor integrated circuit disclosed in JP-A-2005-236277, a coupling pad is disposed in a layer above an active element. Further, a reinforcing structure made of a dummy pattern that does not contribute to a logic function of the circuit is formed between the coupling pad and the active element. Accordingly, damage to the active element due to a stress during wire bonding to the coupling pad is prevented.

However, in the semiconductor integrated circuit in JP-A-2005-236277, since a part of a wiring layer in the semiconductor integrated circuit is used as the dummy pattern, the wiring layer cannot be effectively used, which causes a problem of increasing in size of the semiconductor integrated circuit.

### SUMMARY

A resonator device according to the present application example includes:
a resonator;
an integrated circuit device configured to oscillate the resonator and to generate an oscillation signal;
a container accommodating the resonator and the integrated circuit device; and
a metal bump bonded to the integrated circuit device and electrically coupling the integrated circuit device and the container, in which
the integrated circuit device includes a pad bonded to the metal bump, and a circuit disposed at a position overlapping the metal bump in a plan view of the pad, and
W1/W2≥1.08, where W1 represents a width of the pad, and W2 represents a width of the metal bump.

### BRIEF DESCRIPTION OF THE DRAWINGS

FIG. 1 is a cross-sectional view of a resonator device according to a first embodiment.

FIG. 2 is a plan view of the resonator device shown in FIG. 1.

FIG. 3 is a block diagram showing a circuit configuration of an integrated circuit device.

FIG. 4 is a plan view showing an arrangement of parts provided in the integrated circuit device.

FIG. 5 is a cross-sectional view taken along a line A-A in FIG. 4.

FIG. 6 is a graph showing a relationship between W1/W2 and a stress ratio.

FIG. 7 is a plan view showing definitions of a width W1 and a width W2.

FIG. 8 is a plan view showing the definitions of the width W1 and the width W2.

FIG. 9 is a cross-sectional view of a resonator device according to a second embodiment.

FIG. 10 is a plan view showing an arrangement of parts provided in an integrated circuit provided in a resonator device according to a third embodiment.

### DESCRIPTION OF EXEMPLARY EMBODIMENTS

Hereinafter, a resonator device according to an application example will be described in detail based on embodiments shown in the accompanying drawings.

### First Embodiment

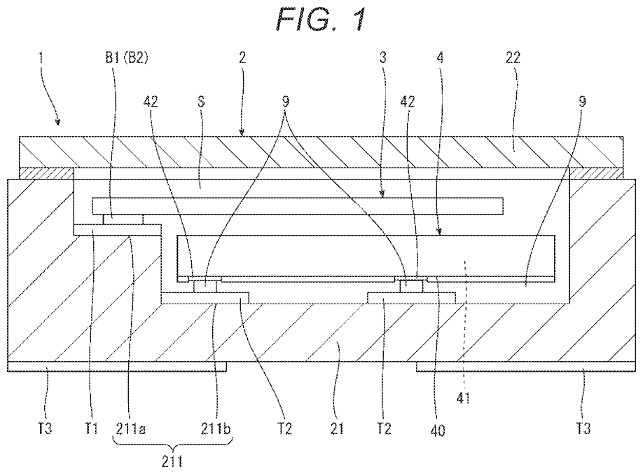

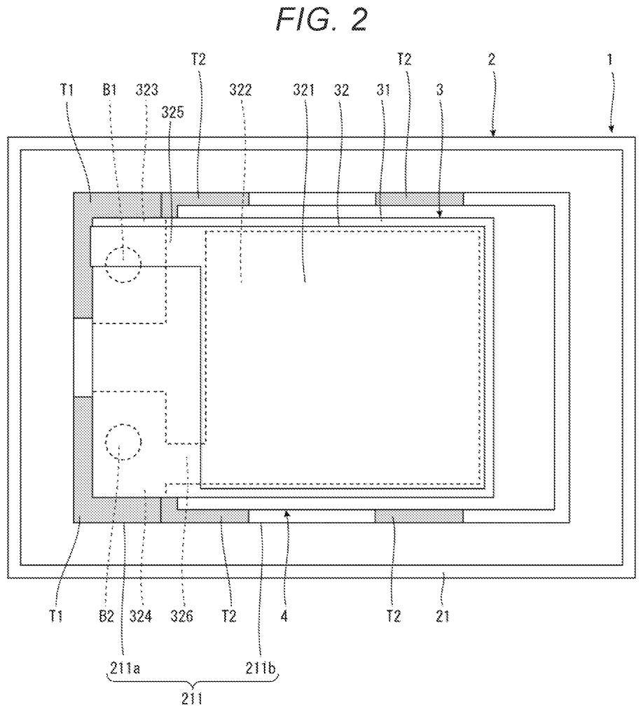

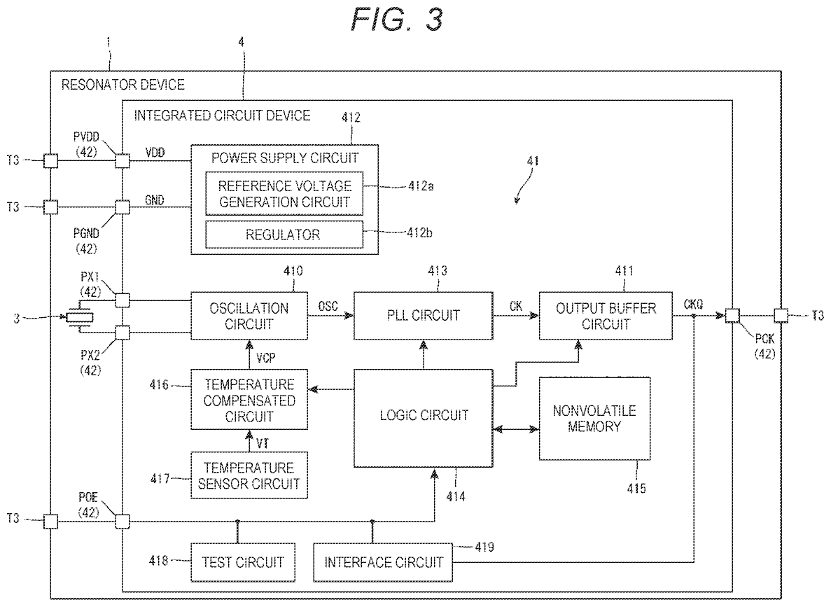

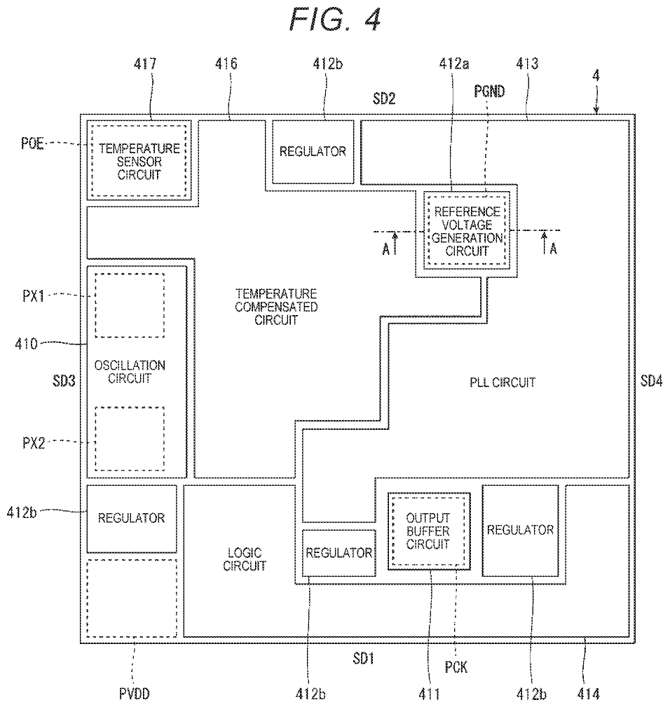

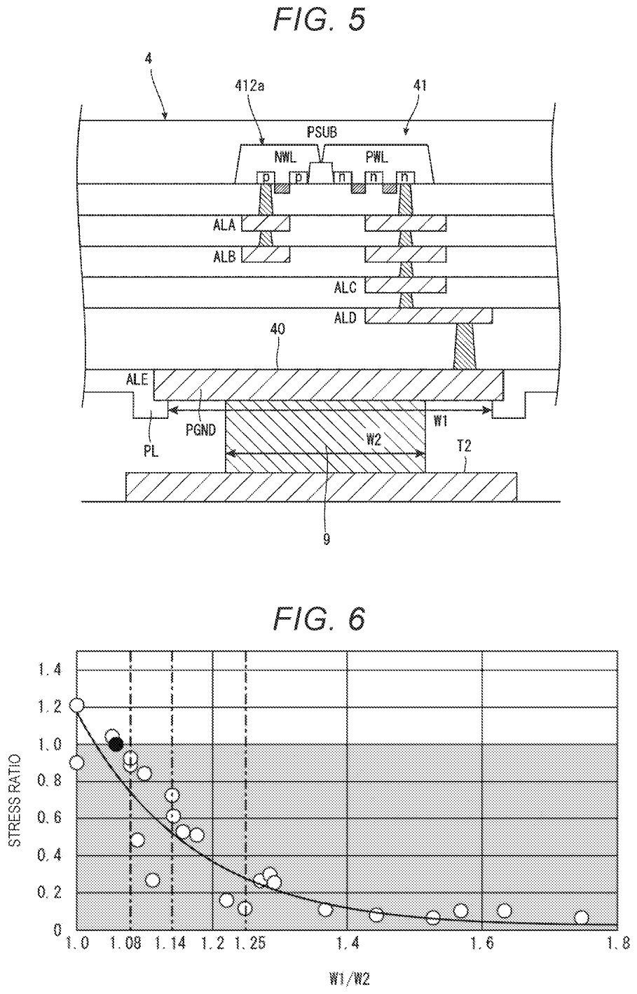

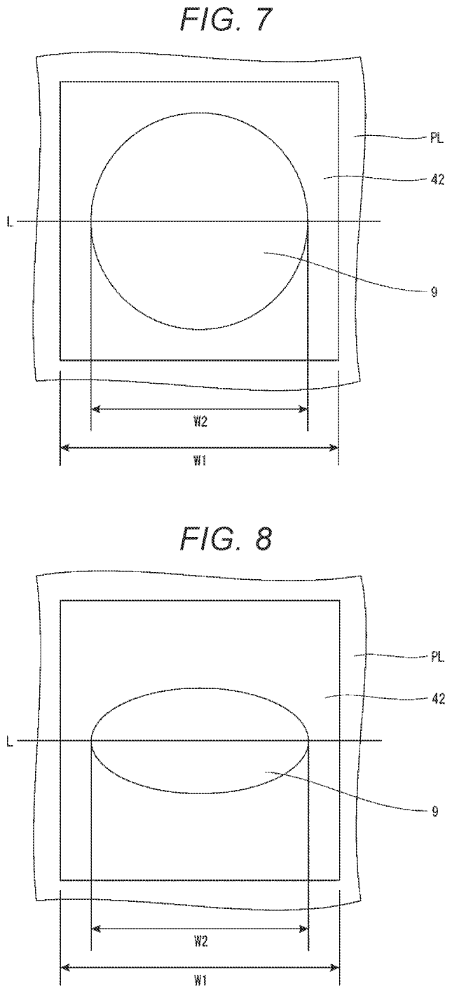

FIG. 1 is a cross-sectional view of a resonator device according to a first embodiment. FIG. 2 is a plan view of the resonator device shown in FIG. 1. FIG. 3 is a block diagram showing a circuit configuration of an integrated circuit device. FIG. 4 is a plan view showing an arrangement of parts provided in the integrated circuit device. FIG. 5 is a cross-sectional view taken along a line A-A in FIG. 4. FIG. 6 is a graph showing a relationship between W1/W2 and a stress ratio. FIGS. 7 and 8 are plan views showing definitions of a width W1 and a width W2, respectively.

A resonator device 1 shown in FIG. 1 is an oscillator, and includes a package 2 as a container, and a resonator 3 and an integrated circuit device 4 that are stored in the package 2.

The package 2 includes a box-shaped base 21 having a recess 211 that opens in an upper surface thereof, and a plate-shaped lid 22 that closes an opening of the recess 211 and that is bonded to the upper surface of the base 21. Since the opening of the recess 211 is closed by the lid 22, a storage space S for storing the resonator 3 and the integrated circuit device 4 is formed. The storage space S is airtight, and is in a reduced pressure state, preferably in a state close to a vacuum. Accordingly, viscous resistance is reduced, and the resonator 3 can be stably driven. However, an atmosphere of the storage space S is not particularly limited.

The recess 211 has a first recess 211a that opens to the upper surface of the base 21, and a second recess 211b that opens to a bottom surface of the first recess 211a and that has an opening smaller than that of the first recess 211a. Further, the resonator 3 is fixed to the bottom surface of the first recess 211a, and the integrated circuit device 4 is fixed to a bottom surface of the second recess 211b. However, the configuration of the recess 211 is not particularly limited.

A pair of coupling terminals T1 are disposed at the bottom surface of the first recess 211a, a plurality of internal terminals T2 are disposed at the bottom surface of the second recess 211b, and a plurality of external terminals T3 are disposed at a lower surface of the base 21. Further, the plurality of internal terminals T2 include a terminal electrically coupled to the coupling terminals T1 via a wiring (not shown) formed in the base 21 and a terminal electrically coupled to the external terminals T3 via a wiring (not shown) formed in the base 21. The pair of coupling terminals T1 are each electrically coupled to the resonator 3 through a respective one of conductive bonding members B1 and B2, and the plurality of internal terminals T2 are each electrically coupled to the integrated circuit device 4 through a respective one of metal bumps 9. Accordingly, the resonator 3 is electrically coupled to the integrated circuit device 4, and the integrated circuit device 4 is electrically coupled to the external terminals T3. Therefore, the resonator device 1 can be electrically coupled to the outside through the external terminals T3.

A constituent material of the base 21 is not particularly limited. For example, various ceramics such as aluminum oxide can be used. On the other hand, a constituent material of the lid 22 is not particularly limited, and a member having a linear expansion coefficient similar to that of the constituent material of the base 21 is preferable. For example, when the constituent material of the base 21 is made of ceramics as described above, it is preferable to use an alloy such as kovar.

As shown in FIG. 2, the resonator 3 includes a resonator substrate 31 which is an AT cut quartz crystal substrate, and an electrode 32 which is disposed at the resonator substrate 31. The AT cut quartz crystal substrate has a thickness-shear resonation mode and has tertiary frequency-temperature characteristics. Therefore, the resonator 3 has excellent temperature characteristics.

The resonator substrate 31 has a rectangular shape, in particular, an oblong shape in a plan view. However, a plan view shape of the resonator substrate 31 is not particularly limited.

The electrode 32 includes a first excitation electrode 321 disposed at an upper surface of the resonator substrate 31, and a second excitation electrode 322 faces the first excitation electrode 321 at a lower surface of the resonator substrate 31. Further, a region sandwiched between the first excitation electrode 321 and the second excitation electrode 322 of the resonator substrate 31 functions as a resonation portion. The electrode 32 includes a first pad 323 and a second pad 324 that are disposed at the lower surface of the resonator substrate 31, a first lead wire 325 electrically coupling the first excitation electrode 321 and the first pad 323, and a second lead wire 326 electrically coupling the second excitation electrode 322 and the second pad 324.

The configuration of the resonator 3 is not limited to the above-described configuration. For example, the resonator substrate 31 is not limited to one formed of the AT cut quartz crystal substrate, and may be formed of a quartz crystal substrate other than the AT cut quartz crystal substrate, for example, an X cut quartz crystal substrate, a Y cut quartz crystal substrate, a Z cut quartz crystal substrate, a BT cut quartz crystal substrate, an SC cut quartz crystal substrate, and an ST cut quartz crystal substrate. A constituent material of the resonator substrate 31 is not limited to the quartz crystal, and may be, for example, a piezoelectric single crystal body such as lithium niobate, lithium tantalate, lithium tetraborate, langasite crystal, potassium niobate, and gallium phosphate, or may be a piezoelectric single crystal body other than these components. The resonator 3 may be a surface acoustic wave (SAW) resonator, a micro electro mechanical systems (MEMS) resonator as a silicon resonator formed using a silicon substrate, or the like.

Such a resonator 3 is bonded to the bottom surface of the first recess 211a through the bonding members B1 and B2. Further, the bonding member B1 is in contact with one coupling terminal T1 and the first pad 323, and electrically couples the coupling terminal T1 and the first pad 323. Similarly, the bonding member B2 is in contact with the other coupling terminal T1 and the second pad 324, and electrically couples the coupling terminal T1 and the second pad 324. That is, the bonding members B1 and B2 mechanically and electrically couple the base 21 and the resonator 3.

The bonding members B1 and B2 are not particularly limited as long as the bonding members have both conductivity and bonding properties. In the embodiment, a conductive adhesive in which a conductive filler such as a silver filler is dispersed in various adhesives such as polyimide-based, epoxy-based, silicone-based, and acrylic-based adhesives is used. By using the conductive adhesive, the bonding members B1 and B2 are relatively soft, and for example, a thermal stress caused by a difference in thermal expansion coefficient between the base 21 and the resonator substrate 31 is mitigated by the bonding members B1 and B2 and is less likely to be transmitted to the resonator 3.

However, as the bonding members B1 and B2, metal bumps such as gold bumps and copper bumps may be used in addition to the conductive adhesive. Accordingly, outgas from the bonding members B1 and B2 can be prevented, and an environmental change in the storage space S, in particular, an increase in pressure can be effectively prevented. Since wetting and spreading of the adhesive or the like do not occur, the bonding members B1 and B2 can be reduced in size, and an interval between the bonding members B1 and B2 can also be narrowed. Therefore, it is possible to reduce the size of the resonator device 1.

As shown in FIG. 1, the integrated circuit device 4 is flip-chip mounted on the bottom surface of the second recess 211b through the metal bumps 9 in a posture in which an active surface 40 faces downward. In general flip-chip mounting, first, the protruding metal bumps 9 are formed on pads 42 of the integrated circuit device 4 to be described later, then the integrated circuit device 4 is reversed and placed at the bottom surface of the second recess 211b, and then the metal bumps 9 are melted by a load from a head and the ultrasonic vibration from an ultrasonic horn, thereby bonding the integrated circuit device 4 to the bottom surface of the second recess 211b. If necessary, a resin may be sealed in a gap between the bottom surface of the second recess 211b and the integrated circuit device 4. According to such flip-chip mounting, space saving can be achieved, and the size of the resonator device 1 can be reduced.

As shown in FIG. 1, the integrated circuit device 4 includes a circuit 41 and the pads 42 exposed to the active surface 40 and electrically coupled to the circuit 41.

As shown in FIG. 3, the circuit 41 includes an oscillation circuit 410, an output buffer circuit 411, a power supply circuit 412, a PLL circuit 413, a logic circuit 414, a nonvolatile memory 415, a temperature compensated circuit 416, a temperature sensor circuit 417, a test circuit 418, and an interface circuit 419. The pads 42 include a power supply pad PVDD, a ground pad PGND, resonator coupling pads PX1 and PX2, a clock pad PCK, and an enable pad POE. Such a circuit 41 is an integrated circuit including passive elements such as transistors and diodes. Alternatively, it can be said that the circuit 41 itself is an active element.

First, circuit blocks in the circuit 41 will be described. The oscillation circuit 410 is a circuit that oscillates the resonator 3. The oscillation circuit 410 is electrically coupled to the resonator 3 through the resonator coupling pads PX1 and PX2, and generates an oscillation signal OSC by oscillating the resonator 3. As the oscillation circuit 410, oscillation circuits of various types such as an inverter type, a Pierce type, a Colpitts type, and a Hartley type can be used.

The power supply circuit 412 is a DC voltage generation circuit and includes a reference voltage generation circuit 412a and regulators 412b. Such a power supply circuit 412 is supplied with a power supply voltage VDD from the power supply pad PVDD and a ground voltage GND from the ground pad PGND, and supplies various power supply voltages for an internal circuit of the integrated circuit device 4 to the internal circuit.

The PLL circuit 413 receives the oscillation signal OSC which is an oscillation clock signal from the oscillation circuit 410, and outputs a clock signal CK that is phase-synchronized with the oscillation signal OSC. Specifically, the PLL circuit 413 outputs the clock signal CK having a frequency obtained by performing phase synchronization with the oscillation signal OSC and multiplying the frequency of the oscillation signal OSC. The PLL circuit 413 is, for example, a fractional-N type PLL circuit capable of fractionally multiplying the frequency of the oscillation signal OSC.

The output buffer circuit 411 buffers the clock signal CK from the PLL circuit 413 and outputs a clock signal CKQ. Then, the clock signal CKQ is output to the outside through the external terminal T3 of the resonator device 1.

The logic circuit 414 is a control circuit and performs various control processes. For example, the logic circuit 414 controls circuit blocks such as the oscillation circuit 410, the output buffer circuit 411, the power supply circuit 412, and the temperature compensated circuit 416. The logic circuit 414 performs write control and read control of the nonvolatile memory 415. The logic circuit 414 is, for example, a circuit of an application specific integrated circuit (ASIC) using an automatic arrangement wiring such as a gate array. The nonvolatile memory 415 stores various types of information used in the integrated circuit device 4.

The temperature sensor circuit 417 is a sensor circuit that detects a temperature of the resonator device 1, in particular, a temperature of the resonator 3. The temperature compensated circuit 416 performs temperature compensation based on temperature detection information obtained from the temperature sensor circuit 417. The temperature compensated circuit 416 generates a temperature compensated voltage VCP based on, for example, a temperature detection voltage VT from the temperature sensor circuit 417, and outputs the generated temperature compensated voltage VCP to the oscillation circuit 410, thereby performing the temperature compensation on the oscillation signal OSC of the oscillation circuit 410.

The test circuit 418 is a circuit for testing the integrated circuit device 4. The test circuit 418 is used to test the circuit block of the integrated circuit device 4. The interface circuit 419 is, for example, a circuit for performing communication of a serial interface. The interface circuit 419 is, for example, a serial interface circuit such as a serial peripheral interface (SPI) or an inter-integrated circuit (I2C).

Next, the pads 42 will be described. The pads 42 are exposed on the active surface of the integrated circuit device 4, and are used to electrically couple the circuit 41 and the outside. Among the pads 42, the power supply pad PVDD is a pad to which the power supply voltage VDD is input. The ground pad PGND is a terminal to which the ground voltage GND is supplied. The clock pad PCK is a pad to which the clock signal CKQ is output. The resonator coupling pads PX1 and PX2 are pads for coupling the resonator 3. The enable pad POE is a pad for controlling an output enable of the clock signal CKQ, that is, ON/OFF of the output of the clock signal CKQ.

Next, the arrangement of the circuit 41 and the pads 42 of the integrated circuit device 4 will be described. The circuit 41 and the pads 42 are disposed as shown in FIG. 4. Specifically, an outer shape of the integrated circuit device 4 is rectangular, and has a total of four sides including a pair of sides SD1 and SD2 facing each other and a pair of sides SD3 and SD4 facing each other.

First, the arrangement of the circuit 41 will be described. The temperature compensated circuit 416 is disposed in the center of the integrated circuit device 4. Further, the PLL circuit 413 is disposed at a corner portion at which the side SD2 and the side SD4 intersect with each other, the logic circuit 414 is disposed at a corner portion at which the side SD1 and the side SD4 intersect with each other, and the temperature sensor circuit 417 is disposed at a corner portion at which the side SD2 and the side SD3 intersect with each other.

The oscillation circuit 410 is disposed between the temperature compensated circuit 416 and the side SD3, the reference voltage generation circuit 412a is disposed between the temperature compensated circuit 416 and the PLL circuit 413, and the output buffer circuit 411 is disposed between the PLL circuit 413 and the logic circuit 414. Further, the regulators 412b are disposed in a scattered manner between the temperature compensated circuit 416 and the PLL circuit 413, between the output buffer circuit 411 and the logic circuit 414, and at a corner portion at which the sides SD1 and SD3 intersect with each other.

Next, the arrangement of the pads 42 will be described. The power supply pad PVDD is disposed at the corner portion at which the side SD1 and the side SD3 intersect with each other. The ground pad PGND overlaps the reference voltage generation circuit 412a. The resonator coupling pads PX1 and PX2 overlap the oscillation circuit 410. The clock pad PCK overlaps the output buffer circuit 411. The enable pad POE overlaps the temperature sensor circuit 417.

Therefore, the metal bumps 9 coupled to the ground pad PGND, the resonator coupling pads PX1 and PX2, the clock pad PCK and the enable pad POE also overlap the circuit 41.

The configuration and the arrangement of the circuit 41 and the pads 42 are described above. However, the configuration and the arrangement of the circuit 41 and the pads 42 are not particularly limited.

Next, a cross-sectional structure of the integrated circuit device 4 will be described. As shown in FIG. 5, the integrated circuit device 4 has a five-layer wiring structure of metal layers ALA to ALE made of aluminum or the like, and the pad 42 is formed of an uppermost metal layer ALE. Specifically, a portion of the metal layer ALE is exposed from an opening of a passivation film PL, and the exposed portion constitutes the pad 42. A P-type well PWL and an N-type well NWL are formed in a P-type substrate PSUB, an N-type transistor constituting the reference voltage generation circuit 412a is formed in the P-type well PWL, and a P-type transistor is formed in the N-type well NWL.

FIG. 5 schematically shows an arrangement relationship between the ground pad PGND and the reference voltage generation circuit 412a. In practice, a layout area of the transistor with respect to a layout area of the ground pad PGND is sufficiently small, and a number of transistors necessary for implementing the reference voltage generation circuit 412a are disposed below the ground pad PGND.

The configuration of the integrated circuit device 4 is briefly described above. As described above, in the integrated circuit device 4, the circuit 41 and the pads 42 overlap in a plan view. Therefore, the space inside the integrated circuit device 4 can be effectively utilized, and the size of the integrated circuit device 4 can be reduced. Since it is not necessary to avoid overlapping with the circuit 41, for example, a degree of freedom in designing a shape and a dimension of the pads 42 increases.

In addition to such an advantage, on the other hand, there is also a disadvantage that a stress applied to the pads 42 during the flip-chip mounting of the integrated circuit device 4 is likely to be transmitted to the circuit 41 immediately below, increasing the risk of damage to the circuit 41. Therefore, in the integrated circuit device 4 according to the embodiment, by designing a dimension ratio between the pads 42 and the metal bumps 9, the stress applied to the pads 42 during the flip-chip mounting is less likely to be transmitted to the circuit 41 immediately below, and damage to the circuit 41 is effectively prevented. Hereinafter, the configuration will be described in detail.

As shown in FIG. 5, in the integrated circuit device 4 according to the embodiment, W1/W2≥1.08, where a width of the pad 42 is W1 and a width of the metal bump 9 is W2. By satisfying such a relationship, it is possible to reduce a force applied immediately below the pads 42 when the flip-chip mounting is performed, and it is possible to effectively prevent the damage to the circuit 41 overlapping the pads 42. According to such a configuration, it is not necessary to dispose a dummy pattern as in the related art, and it is not necessary to dispose the circuit 41 in a manner of avoiding a region immediately below the pads 42. Therefore, since the circuit 41 can be disposed using the space in the integrated circuit device 4 without waste, the size of the integrated circuit device 4 can be reduced. The effect will be described below with reference to a graph in FIG. 6.

The graph in FIG. 6 is a graph showing a relationship between W1/W2 and a stress ratio when the flip-chip mounting is performed by applying a constant stress. FIG. 6 is obtained by an experiment. The stress ratio means a ratio between a reference value and a stress value actually applied immediately below the pads 42. A stress value applied immediately below the pads 42 in a configuration in which a crack is generated in the circuit 41 (W1/W2=1.06) is used as the reference value. Therefore, when the stress ratio exceeds 1.0, the crack may be generated in the circuit 41 and the circuit 41 may be damaged. When the stress ratio is less than 1.0, there is a high possibility that the crack is not generated in the circuit 41 and the circuit 41 is not damaged. Therefore, it can be seen from the graph that when W1/W2≥1.08, the stress ratio is 1.0 or less, and there is a high possibility that the crack is not generated in the circuit 41 and the circuit 41 is not damaged. That is, as described above, by setting W1/W2≥1.08, damage to the circuit 41 can be effectively prevented.

It is sufficient that at least one of the pads 42 overlapping the metal bumps 9 and the circuit 41 satisfies the above relationship, and it is preferable that the relationship is satisfied in all of the pads 42. Accordingly, the above-described effect is more remarkable. There are a plurality of pads 42 overlapping the metal bumps 9 and the circuit 41. The present disclosure is not limited thereto, and the number of pads may be one.

Here, the width W2 is a maximum width of the metal bumps 9 in a plan view. That is, as shown in FIG. 7, when the metal bump 9 is circular, the width W2 of the metal bump 9 is a diameter thereof. As shown in FIG. 8, when the metal bump 9 is elliptical, the width W2 is a length of a long axis thereof. The width W1 means a width of the pad 42 on extension lines of the width W2. That is, as shown in FIG. 7, when the metal bump 9 is circular, the width W1 means a width of any straight line L passing through the center of the metal bump 9. In this case, there are numerous straight lines L, and it is sufficient that the width on at least one straight line L satisfies the above relationship. That is, as shown in FIG. 8, when the metal bump 9 is elliptical, the width W1 means a width on the straight line L overlapping the long axis.

The present disclosure is not particularly limited as long as W1/W2≥1.08. W1/W2≥1.14 is preferable, W1/W2≥1.20 is more preferable, and W1/W2≥1.25 is still more preferable. By satisfying such a relationship, the stress applied immediately below the pads 42 during the flip-chip mounting is further reduced, and the damage to the circuit 41 can be more effectively prevented.

Further, since the reduction in the stress ratio is blunted (saturated) around W1/W2≤1.8, an upper limit of W1/W2 is, for example, preferably W1/W2≤2.4, and more preferably W1/W2≤1.8. Accordingly, an excessive increase in the size of the pads 42 or an excessive reduction in the size of the metal bumps 9 can be prevented. When the pads 42 are excessively large, wiring efficiency of the integrated circuit device 4 is reduced, which may cause an increase in size of the integrated circuit device 4. On the other hand, when the metal bumps 9 are excessively small, a mechanical strength and a bonding strength of the metal bumps 9 are reduced, and reliability of the resonator device 1 may be reduced. Therefore, by setting W1/W2≤2.4, it is possible to prevent the reduction in the wiring efficiency of the integrated circuit device 4 and the reduction in the mechanical strength of the metal bump 9, and the integrated circuit device 4 having a small size and high reliability is obtained.

The graph in FIG. 6 shows results obtained from the experiment and a simulation using the metal bumps 9 having the width W2 of 85 μm. The width W2 is not particularly limited, and may be, for example, about 50 μm or more and 120 μm or less. In such a range, it is also confirmed that a tendency same as in FIG. 6 is obtained.

The configuration of the integrated circuit device 4 is briefly described above, and the configuration and the arrangement of the circuit 41, and the configuration and the arrangement of the pads 42 are not particularly limited.

The resonator device 1 is described above. As described above, such a resonator device 1 includes the resonator 3, the integrated circuit device 4 that oscillates the resonator 3 and that generates an oscillation signal, the package 2 that is a container accommodating the resonator 3 and the integrated circuit device 4, and the metal bumps 9 that are bonded to the integrated circuit device 4 and that electrically couple the integrated circuit device 4 and the package 2. The integrated circuit device 4 includes the pads 42 bonded to the metal bumps 9, and the circuit 41 disposed at a position overlapping the metal bumps 9 in a plan view of the pads 42. Further, W1/W2≥1.08, where the width of the pads 42 is W1 and the width of the metal bumps 9 is W2.

According to such a configuration, it is possible to reduce a force applied immediately below the pads 42 when the integrated circuit device 4 is mounted on the package 2. Therefore, it is not necessary to dispose a dummy pattern as in the related art, and it is not necessary to dispose the circuit 41 in a manner of avoiding a region immediately below the pads 42. Therefore, since the circuit 41 can be disposed using the space in the integrated circuit device 4 without waste, the size of the integrated circuit device 4 can be reduced. As a result, it is possible to reduce the size of the resonator device 1.

As described above, W1/W2≥1.14 is preferable. Accordingly, it is possible to further reduce the force applied immediately below the pads 42 when the integrated circuit device 4 is mounted on the package 2.

As described above, W1/W2≥1.20 is preferable. Accordingly, it is possible to further reduce the force applied immediately below the pads 42 when the integrated circuit device 4 is mounted on the package 2.

As described above, W1/W2≥1.25 is preferable. Accordingly, it is possible to further reduce the force applied immediately below the pads 42 when the integrated circuit device 4 is mounted on the package 2.

As described above, W1/W2≤2.40 is preferable. Accordingly, an excessive increase in the size of the pads 42 or an excessive reduction in the size of the metal bumps 9 can be prevented. Therefore, it is possible to prevent the reduction in the wiring efficiency of the integrated circuit device 4 and the reduction in the mechanical strength of the metal bumps 9, and the integrated circuit device 4 having a small size and high reliability is obtained.

As described above, the integrated circuit device 4 is flip-chip mounted on the package 2 through the metal bumps 9. Accordingly, space saving can be achieved, and the size of the resonator device 1 can be reduced.

As described above, the circuit is the circuit 41 including the active element. Accordingly, further space saving can be achieved.

### Second Embodiment

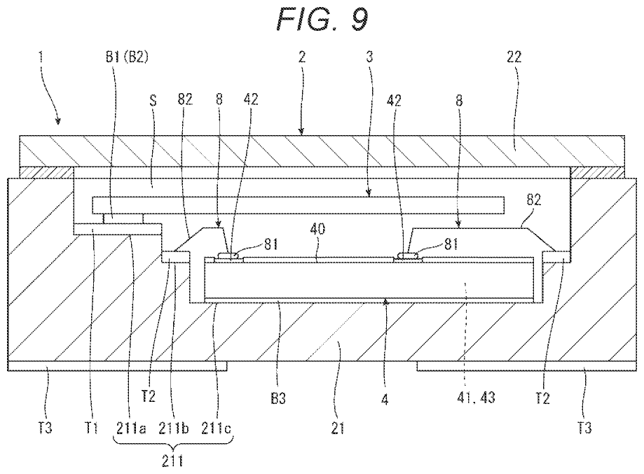

FIG. 9 is a cross-sectional view of a resonator device according to a second embodiment.

The resonator device 1 according to the embodiment is the same as the resonator device 1 according to the first embodiment except that a method for electrically coupling the integrated circuit device 4 and the package is different. In the following description, the resonator device 1 according to the embodiment will be described focusing on the differences from the first embodiment described above, and the description of the same matters will be omitted. In the drawings of the embodiment, configurations similar to those of the above-described embodiment will be denoted by the same reference signs.

In the resonator device 1 according to the embodiment, the integrated circuit device 4 and the package 2 are electrically coupled by wire bonding, in particular, by ball bonding. When the wire bonding is performed, the pads 42 are set to first bonding, and metal bumps 81 are formed on the pads 42. The metal bumps 81 are also referred to as balls. Hereinafter, the configuration will be described in detail.

First, in the embodiment, as shown in FIG. 9, the recess 211 of the base 21 includes the first recess 211a that opens to an upper surface of the base 21, a second recess 211b that opens to a bottom surface of the first recess 211a and that has an opening smaller than that of the first recess 211a, and a third recess 211c that opens to a bottom surface of the second recess 211b and that has an opening smaller than that of the second recess 211b. Further, the resonator 3 is fixed to the bottom surface of the first recess 211a, and the integrated circuit device 4 is fixed to a bottom surface of the third recess 211c.

The integrated circuit device 4 is fixed to the bottom surface of the third recess 211c in a reversed posture from the first embodiment, that is, in a posture in which the active surface 40 faces upward. The integrated circuit device 4 is fixed to the bottom surface of the third recess 211c through a bonding member B3. The bonding member B3 is not particularly limited. For example, various adhesives such as polyimide-based, epoxy-based, silicone-based, and acrylic-based adhesives can be used.

The pair of coupling terminals T1 are disposed at the bottom surface of the first recess 211a, the plurality of internal terminals T2 are disposed at the bottom surface of the second recess 211b, and the plurality of external terminals T3 are disposed at a lower surface of the base 21. Further, the plurality of internal terminals T2 include a terminal electrically coupled to the coupling terminals T1 via a wiring (not shown) formed in the base 21 and a terminal electrically coupled to the external terminals T3 via a wiring (not shown) formed in the base 21. The pair of coupling terminals T1 are each electrically coupled to the resonator 3 through a respective one of conductive bonding members B1 and B2, and the plurality of internal terminals T2 are each electrically coupled to the integrated circuit device 4 through a respective one of bonding wires 8.

The bonding wires 8 each include the metal bump 81 bonded to the pad 42, and a wire 82 extending from the metal bump 81 and having a base end thereof bonded to the internal terminal T2. According to such a bonding wire 8, the integrated circuit device 4 and the package 2 can be easily electrically coupled to each other.

As described above, in the resonator device 1 according to the embodiment, the integrated circuit device 4 is electrically coupled to the package 2 through the bonding wires 8 each including the metal bump 81 and the wire 82 extending from the metal bump 81. Accordingly, the integrated circuit device 4 and the package 2 can be easily electrically coupled to each other.

The second embodiment can also exert the same effect as that of the first embodiment described above.

### Third Embodiment

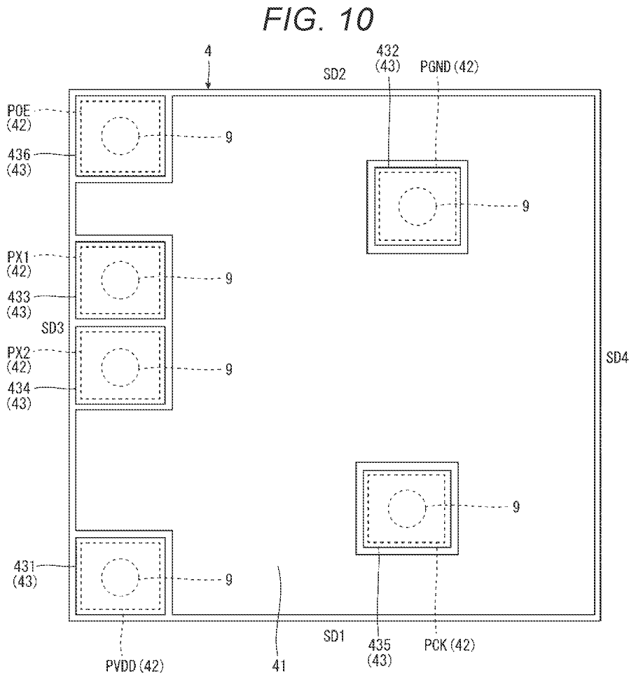

FIG. 10 is a plan view showing an arrangement of parts provided in an integrated circuit provided in a resonator device according to a third embodiment.

The resonator device 1 according to the embodiment is the same as the resonator device 1 according to the first embodiment except that a configuration of the integrated circuit device 4 is different. In the following description, the resonator device 1 according to the embodiment will be described focusing on the differences from the first embodiment described above, and the description of the same matters will be omitted. In the drawings of the embodiment, configurations similar to those of the above-described embodiment will be denoted by the same reference signs.

As shown in FIG. 10, the integrated circuit device 4 according to the embodiment includes a static electricity protection circuit 43 that protects the circuit 41 from an abnormal voltage such as static electricity. The static electricity protection circuit 43 overlaps the pads 42. Hereinafter, the static electricity protection circuit 43 will be described.

The static electricity protection circuit 43 includes a first static electricity protection circuit 431, a second static electricity protection circuit 432, a third static electricity protection circuit 433, a fourth static electricity protection circuit 434, a fifth static electricity protection circuit 435, and a sixth static electricity protection circuit 436.

The first static electricity protection circuit 431 is electrically coupled to the power supply pad PVDD, and overlaps the metal bump 9 on the power supply pad PVDD in a plan view. Further, the first static electricity protection circuit 431 absorbs charges due to large external noise such as the static electricity applied to the power supply pad PVDD, and protects the circuit block electrically coupled to the power supply pad PVDD from external noise.

The second static electricity protection circuit 432 is electrically coupled to the ground pad PGND, and overlaps the metal bump 9 on the ground pad PGND in the plan view. Further, the second static electricity protection circuit 432 absorbs charges due to large external noise such as the static electricity applied to the ground pad PGND, and protects the circuit block electrically coupled to the ground pad PGND from external noise.

The third static electricity protection circuit 433 is electrically coupled to the resonator coupling pad PX1, and overlaps the metal bump 9 on the resonator coupling pad PX1 in the plan view. Further, the third static electricity protection circuit 433 absorbs charges due to large external noise such as the static electricity applied to the resonator coupling pad PX1, and protects the circuit block electrically coupled to the resonator coupling pad PX1 from external noise.

The fourth static electricity protection circuit 434 is electrically coupled to the resonator coupling pad PX2, and overlaps the metal bump 9 on the resonator coupling pad PX2 in the plan view. Further, the fourth static electricity protection circuit 434 absorbs charges due to large external noise such as the static electricity applied to the resonator coupling pad PX2, and protects the circuit block electrically coupled to the resonator coupling pad PX2 from external noise.

The fifth static electricity protection circuit 435 is electrically coupled to the clock pad PCK, and overlaps the metal bump 9 on the clock pad PCK in the plan view. Further, the fifth static electricity protection circuit 435 absorbs charges due to large external noise such as the static electricity applied to the clock pad PCK, and protects the circuit block electrically coupled to the clock pad PCK from external noise.

The sixth static electricity protection circuit 436 is electrically coupled to the enable pad POE, and overlaps the metal bump 9 on the enable pad POE in the plan view. Further, the sixth static electricity protection circuit 436 absorbs charges due to large external noise such as the static electricity applied to the enable pad POE, and protects the circuit block electrically coupled to the enable pad POE from external noise.

The first static electricity protection circuit 431, the second static electricity protection circuit 432, the third static electricity protection circuit 433, the fourth static electricity protection circuit 434, the fifth static electricity protection circuit 435, and the sixth static electricity protection circuit 436 are not particularly limited. For example, a circuit using a TVS diode (an ESD protection diode) can be used.

However, the static electricity protection circuit 43 is not particularly limited. For example, at least one of the first static electricity protection circuit 431, the second static electricity protection circuit 432, the third static electricity protection circuit 433, the fourth static electricity protection circuit 434, the fifth static electricity protection circuit 435, and the sixth static electricity protection circuit 436 may be omitted.

As described above, in the embodiment, the static electricity protection circuit 43 overlaps the pads 42. Therefore, it is possible to reduce a force applied to the static electricity protection circuit 43 when the integrated circuit device 4 is flip-chip mounted. Therefore, it is possible to effectively prevent damage to the static electricity protection circuit 43.

As described above, in the resonator device 1 according to the embodiment, the circuit disposed at the position overlapping the metal bumps 9 is the static electricity protection circuit 43. Accordingly, it is possible to effectively prevent the damage to the static electricity protection circuit 43.

As described above, although the resonator device according to the present disclosure is described based on the illustrated embodiments, the present disclosure is not limited thereto. A configuration of each part can be replaced with any configuration having a similar function. Further, any other components may be added to the present disclosure. The present disclosure may be a combination of two or more configurations among the above-described embodiments.

What is claimed is:

1. A resonator device comprising:
a resonator;
an integrated circuit device configured to oscillate the resonator and to generate an oscillation signal;
a container accommodating the resonator and the integrated circuit device; and
a metal bump bonded to the integrated circuit device and electrically coupling the integrated circuit device and the container, wherein
the integrated circuit device includes a pad bonded to the metal bump, and a circuit disposed at a position overlapping the metal bump in a plan view of the pad, and
W1/W2≥1.08, wherein W1 represents a width of the pad, and W2 represents a width of the metal bump.

2. The resonator device according to claim 1, wherein
W1/W2≥1.14.

3. The resonator device according to claim 2, wherein
W1/W2≥1.20.

4. The resonator device according to claim 3, wherein
W1/W2≥1.25.

5. The resonator device according to claim 1, wherein
W1/W2≤2.40.

6. The resonator device according to claim 1, wherein
the integrated circuit device is flip-chip mounted on the container through the metal bump.

7. The resonator device according to claim 1, wherein
the integrated circuit device is electrically coupled to the container through a bonding wire including the metal bump and a wire extending from the metal bump.

8. The resonator device according to claim 1, wherein
the circuit is a static electricity protection circuit.

9. The resonator device according to claim 1, wherein
the circuit is a circuit including an active element.
